(19) United States
(12) Patent Application Publication
(10) Pub. No.: US 2026/0219462 A1
(43) Pub. Date: Jul. 30, 2026

(54) OPTICAL MODULE AND FABRICATION METHOD FOR HYBRID INP/SI OPTICAL CHIP

(71) Applicant: HISENSE BROADBAND MULTIMEDIA TECHNOLOGIES CO., LTD., Qingdao (CN)

(72) Inventors: Jianying ZHOU, Qingdao (CN); Hongmin CHEN, Qingdao (CN); Jin HONG, Qingdao (CN)

(21) Appl. No.: 19/630,062

(22) Filed: Mar. 26, 2026

Related U.S. Application Data
(63) Continuation of application No. PCT/CN2024/090152, filed on Apr. 26, 2024.

(30) Foreign Application Priority Data
Sep. 28, 2023 (CN) 202311270743.6
Jan. 31, 2024 (CN) 202410135176.1
Jan. 31, 2024 (CN) 202410135674.6

(51) Int. Cl. G02B 6/42; H10D 80/20

(52) U.S. Cl. CPC G02B 6/4259; G02B 6/4261; G02B 6/4278; G02B 6/4279; G02B 6/428; H10D 80/213; H10D 80/215

(57) ABSTRACT

An optical module and a fabrication method for a hybrid InP/Si optical chip. The optical module includes a circuit board and a hybrid InP/Si optical chip. The hybrid InP/Si optical chip includes: an Si platform having a silicon photonic circuit and is formed with an InP region without a pad, a radio frequency pad and a direct current bias pad are disposed on a top of the Si platform; an InP phase modulator within the InP region, the InP phase modulator includes an InP waveguide electrically connected to the direct current bias pad and a coupling electrode disposed above the InP waveguide; and a radio frequency traveling waveguide connected, with one end, to the radio frequency pad, and the other end extending over the InP waveguide to the other side of the InP region, the radio frequency traveling waveguide is electrically connected to the coupling electrode.

The present application is a continuation of International Application No. PCT/CN2024/090152, filed on April 26, 2024, which claims priority to Chinese Patent Application No. 202311270743.6, filed with the China National Intellectual Property Administration on September 28, 2023, priority to Chinese Patent Application No. 202410135176.1, filed with the China National Intellectual Property Administration on January 31, 2024, and priority to Chinese Patent Application No. 202410135674.6, filed with the China National Intellectual Property Administration on January 31, 2024. The entire contents of all of the above-mentioned applications are incorporated herein by reference.

### FIELD OF THE INVENTION

The present disclosure relates to the field of optical fiber communication technology, and in particular, to an optical module and a fabrication method for a hybrid InP/Si optical chip.

### BACKGROUND OF THE INVENTION

With the development of new services and application models such as cloud computing, mobile Internet, and video, advances in optical communication technology have become increasingly important. In an optical communication technology, the optical module is one of the key devices in optical communication equipment and can implement optical-electrical signal conversion. During development of the optical communication technology, a data transmission rate of optical modules is required to continuously increase.

### SUMMARY OF THE INVENTION

The present disclosure provides an optical module and a fabrication method for a hybrid InP/Si optical chip, which meets requirements for high-rate optical modules.

In a first aspect, an optical module provided in the present disclosure includes:

a circuit board; and

a hybrid InP/Si optical chip, electrically connected to the circuit board, and configured to modulate and generate an optical signal;

where the hybrid InP/Si optical chip includes:

an Si platform, where an InP region is formed inside the Si platform, a pad is absent from a top of InP region, a radio frequency pad and a direct current bias pad are disposed on a top of the Si platform, the radio frequency pad is located on one side of the InP region, and the direct current bias pad is located on the other side of the InP region;

an InP phase modulator, located within the InP region, where the InP phase modulator includes an InP waveguide and a coupling electrode, the coupling electrode is disposed above the InP waveguide, and the InP waveguide is electrically connected to the direct current bias pad; and

a radio frequency traveling waveguide, one end of the radio frequency traveling waveguide being connected to the radio frequency pad, and the other end of the radio frequency traveling waveguide extending over the InP waveguide and further extending to the other side of the InP region, wherein the radio frequency traveling waveguide is electrically connected to the coupling electrode;

the radio frequency pad comprises a first radio frequency pad and a second radio frequency pad, the radio frequency traveling waveguide comprises a first radio frequency electrode and a second radio frequency electrode, one end of the first radio frequency electrode is connected to the first radio frequency pad, and one end of the second radio frequency electrode is connected to the second radio frequency pad;

the first radio frequency electrode spans the InP region along one side of a top of the InP waveguide, and the second radio frequency electrode spans the InP region along the other side of a top of the InP waveguide;

the first radio frequency electrode extends from one side outside the InP region to the other side outside the InP region, and the second radio frequency electrode extends from one side outside the InP region to the other side outside the InP region; and

the Si platform includes a substrate layer, a BOX layer is disposed above the substrate layer, an Si waveguide layer and an SiO₂ layer are disposed above the BOX layer, the Si waveguide layer is encapsulated by the SiO₂ layer, the Si waveguide layer includes a strip-shaped Si waveguide, and a top of the SiO₂ layer supports the first radio frequency electrode and the second radio frequency electrode.

In a second aspect, a fabrication method for a hybrid InP/Si optical chip is provided by the present disclosure, where the hybrid InP/Si optical chip is configured to modulate and generate an optical signal, and the fabrication method includes:

forming a first substrate, where the first substrate includes a substrate layer and a BOX layer, and the BOX layer is located above the substrate layer;

forming an Si waveguide layer above the BOX layer, and etching the Si waveguide layer to form an input Si waveguide and an output Si waveguide, where a gap is formed between the input Si waveguide and the output Si waveguide;

forming a first SiO₂ layer around the etched Si waveguide layer, where the first SiO₂ layer fills a region that is of the Si waveguide layer and etched away;

disposing an InP bare die above the first SiO₂ layer;

etching the InP bare die to form an InP waveguide;

forming a second SiO₂ layer on a side of the InP waveguide, wherein the first SiO₂ layer and the second SiO₂ layer together form an SiO₂ layer, and the Si waveguide layer is encapsulated by the SiO₂ layer; and

forming a radio frequency pad, a direct current bias pad, a radio frequency traveling waveguide, and a coupling electrode on a top of the second SiO₂ layer; wherein the radio frequency pad is disposed at a side of one end of the InP waveguide, the radio frequency traveling waveguide is disposed at a side of a top edge of the InP waveguide, and one end of the radio frequency traveling waveguide is electrically connected to the radio frequency pad; the direct current bias pad is located at a side of the other end of the InP waveguide, and the direct current bias pad is electrically connected to the InP waveguide; the coupling electrode is located above the InP waveguide; and the coupling electrode is electrically connected to the radio frequency traveling waveguide.

### BRIEF DESCRIPTION OF THE DRAWINGS

To more clearly illustrate the technical solution in the embodiments of the present disclosure, the accompanying drawings that need to be used in the description of the embodiments or the prior art will be briefly introduced below. Apparently, the accompanying drawings in the description below merely illustrate some embodiments of the present disclosure. Those of ordinary skill in the art may also derive other accompanying drawings from these accompanying drawings without creative efforts.

FIG. 1 is a partial architecture diagram of an optical communication system according to some embodiments of the present disclosure;

FIG. 2 is a partial structural diagram of a host computer according to some embodiments of the present disclosure;

FIG. 3 is a structural diagram of an optical module according to some embodiments of the present disclosure;

FIG. 4 is an exploded view of an optical module according to some embodiments of the present disclosure;

FIG. 5 is a schematic diagram of an internal structure of an optical module according to some embodiments of the present disclosure;

FIG. 6 is a schematic layout diagram of a silicon photonic chip according to some embodiments of the present disclosure;

FIG. 7 is a schematic layout diagram of a hybrid InP/Si optical chip according to some embodiments of the present disclosure;

FIG. 8 is a first partial structural diagram of a hybrid InP/Si optical chip according to some embodiments of the present disclosure;

FIG. 9 is a second partial structural diagram of a hybrid InP/Si optical chip according to some embodiments of the present disclosure;

FIG. 10 is a schematic structural diagram of a first radio frequency electrode according to some embodiments of the present disclosure;

FIG. 11 is a first enlarged sectional view of a hybrid InP/Si optical chip according to some embodiments of the present disclosure;

FIG. 12 is a second enlarged sectional view of a hybrid InP/Si optical chip according to some embodiments of the present disclosure;

FIG. 13 is a third enlarged sectional view of a hybrid InP/Si optical chip according to some embodiments of the present disclosure;

FIG. 14 is a fourth enlarged sectional view of a hybrid InP/Si optical chip according to some embodiments of the present disclosure;

FIG. 15 is an equivalent circuit diagram of a hybrid InP/Si optical chip according to some embodiments of the present disclosure;

FIG. 16 is a first schematic structural diagram of a hybrid InP/Si optical chip assembly according to some embodiments of the present disclosure;

FIG. 17 is a second schematic structural diagram of a hybrid InP/Si optical chip assembly according to some embodiments of the present disclosure; and

FIG. 18 is a flowchart of a fabrication method for a hybrid InP/Si optical chip according to some embodiments of the present disclosure.

### DETAILED DESCRIPTION OF THE EMBODIMENTS

The technical solutions in some embodiments of the present disclosure will be clearly and completely described below with reference to the accompanying drawings. Apparently, the described embodiments are merely some rather than all of the embodiments of the present disclosure. All other embodiments obtained by those of ordinary skill in the art based on the embodiments provided in the present disclosure fall within the scope of protection of the present disclosure.

Unless the context requires otherwise, throughout the description and claims, the term "comprise" and other forms thereof, such as the third-person singular form "comprises" and the present participle form "comprising" are construed in an open, inclusive meaning, that is, "comprising, but not limited to". In the description, the terms "one embodiment," "some embodiments," "exemplary embodiments," "example," "specific example," or "some examples," etc. are intended to indicate that a particular feature, structure, material, or characteristic related to the embodiment or example is included in at least one embodiment or example of the present disclosure. The schematic illustration of the above terms does not necessarily refer to the same embodiment or example. Furthermore, the specific features, structures, materials, or characteristics described may be included in any one or more embodiments or examples in any suitable manner.

Hereinafter, the terms "first" and "second" are for descriptive purposes only, and are not to be understood as indicating or implying relative importance or as implicitly indicating the number of technical features indicated. Thus, the use of terms like "first" and "second" to describe features can explicitly or implicitly encompass one or more of such features. In the description of embodiments of the present disclosure, unless otherwise specified, "a plurality" means two or more.

In describing some embodiments, the expressions "coupled" and "connected" and extensions thereof may be used. For example, in describing some embodiments, the term "connected" may be used to indicate that two or more components are in direct physical contact or electrical contact with each other. For another example, in describing some embodiments, the term "coupled" may be used to indicate that two or more components are in direct physical contact or electrical contact with each other. However, the term "coupled" or "communicatively coupled" may also indicate that two or more components are not in direct contact with each other, but still cooperate or interact with each other. The embodiments disclosed herein are not necessarily limited to the contents herein.

"At least one of A, B, and C" has the same meaning as "at least one of A, B, or C", encompassing the following combinations of A, B, and C: only A, only B, only C, a combination of A and B, a combination of A and C, a combination of B and C, as well as a combination of A, B, and C.

"A and/or B" includes three combinations of only A, only B, and a combination of A and B.

The use of "suitable for" or "configured to" herein means open and inclusive language that does not exclude devices suitable for or configured to perform additional tasks or steps.

As used herein, "about," "approximately," or "approximately" includes a stated value as well as an average within an acceptable range of deviation from a particular value, where the acceptable range of deviation is determined by one of ordinary skill in the art taking into account the measurement in question and the error associated with the measurement of a particular amount (i.e., limitations of the measurement system).

In optical communication technology, in order to establish information transmission between information processing devices, it is necessary to load information onto light and use the propagation of light to achieve the transmission of information. Here, the light loaded with information is an optical signal. When the optical signal is transmitted in the information transmission devices, the loss of optical power can be reduced, such that high-speed, long-distance, and low-cost information transmission can be achieved. The signals that the information processing devices are able to recognize and process are electrical signals. The information processing devices usually include optical network units (ONUs), gateways, routers, switches, mobile phones, computers, servers, tablet computers, televisions, etc. The information transmission devices usually include optical fibers and optical waveguides.

The optical modules can achieve the conversion between optical signals and electrical signals from the information processing devices and the information transmission devices. For example, at least one of an optical signal input or an optical signal output of an optical module is connected to an optical fiber, and at least one of an electrical signal input or an electrical signal output of the optical module is connected to an optical network unit; a first optical signal from the optical fiber is transmitted to the optical module, and the optical module converts the first optical signal into a first electrical signal and transmits the first electrical signal to the optical network unit; and a second electrical signal from the optical network unit is transmitted to the optical module, and the optical module converts the second electrical signal into a second optical signal and transmits the second optical signal to the optical fiber. Since information can be transmitted through electrical signals between a plurality of information processing devices, at least one information processing device in the plurality of information processing devices is required to be directly connected to the optical module, and all information processing devices are not required to be directly connected to the optical module. Here, the information processing device directly connected to the optical module is referred to as a host computer of the optical module. In addition, the optical signal input or the optical signal output of the optical module can be referred to as an optical port, and the electrical signal input or the electrical signal output of the optical module can be referred to as an electrical port.

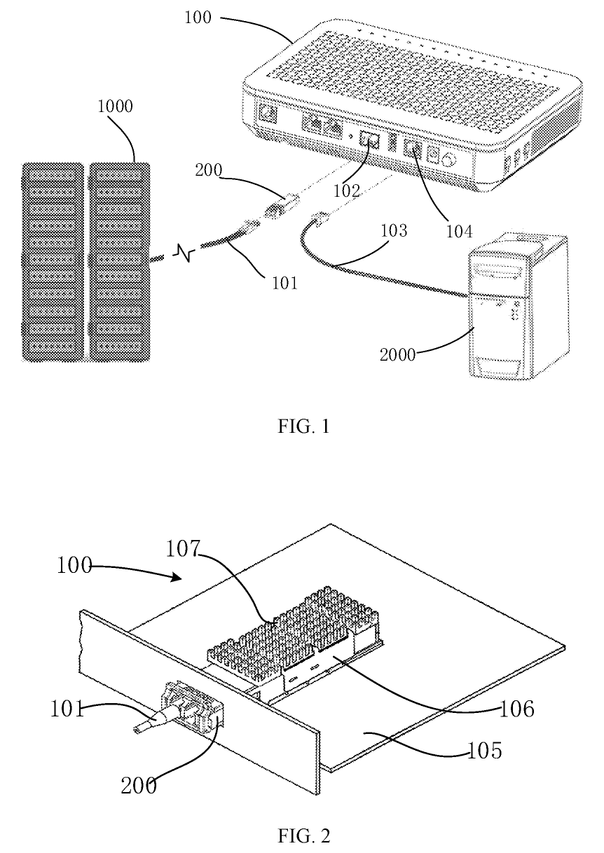

FIG. 1 is a partial structural diagram of an optical communication system according to some embodiments of the present disclosure. As shown in FIG. 1, the optical communication system primarily includes a remote information processing device 1000, a local information processing device 2000, a host computer 100, an optical module 200, an optical fiber 101 and a network cable 103.

One end of the optical fiber 101 extends toward the remote information processing device 1000, and the other end of the optical fiber 101 is connected to the optical module 200 via an optical port of the optical module 200. An optical signal can undergo total reflection in the optical fiber 101, and the propagation of the optical signal in a total reflection direction can almost maintain its original optical power. The optical signal undergoes multiple total reflections in the optical fiber 101 to transmit an optical signal from the remote information processing device 1000 to the optical module 200 or to transmit an optical signal from the optical module 200 to the remote information processing device 1000, thereby implementing long-distance and low-power-loss information transmission.

The optical communication system may include one or more optical fibers 101, and the optical fiber 101 is detachably or fixedly connected to the optical module 200. The host computer 100 is configured to provide a data signal to the optical module 200, receive a data signal from the optical module 200, or monitor or control a working state of the optical module 200.

The host computer 100 includes a generally cuboid-shaped shell, and an optical module interface 102 arranged on the shell. The optical module interface 102 is configured to be connected to the optical module 200, enabling the host computer 100 to establish a one-way or two-way electrical signal connection with the optical module 200.

The host computer 100 further includes an external electrical interface that can be connected to an electrical signal network. For example, the external electrical interface includes a universal serial bus (USB) interface or a network cable interface 104. The network cable interface 104 is configured to be connected to the network cable 103, enabling the host computer 100 to establish a one-way or two-way electrical signal connection with the network cable 103. One end of the network cable 103 is connected to the local information processing device 2000, and the other end of the network cable 103 is connected to the host computer 100, thereby establishing an electrical signal connection between the local information processing device 2000 and the host computer 100 via the network cable 103. For example, a third electrical signal sent by the local information processing device 2000 is transmitted to the host computer 100 via the network cable 103. The host computer 100 generates a second electrical signal according to the third electrical signal. The second electrical signal from the host computer 100 is transmitted to the optical module 200. The optical module 200 converts the second electrical signal into a second optical signal and transmits the second optical signal to the optical fiber 101. The second optical signal is transmitted through the optical fiber 101 to the remote information processing device 1000. For example, a first optical signal from the remote information processing device 1000 is transmitted through the optical fiber 101. The first optical signal from the optical fiber 101 is transmitted to the optical module 200. The optical module 200 converts the first optical signal into a first electrical signal, and then the optical module 200 transmits the first electrical signal to the host computer 100. The host computer 100 generates a fourth electrical signal according to the first electrical signal and transmits the fourth electrical signal to the local information processing device 2000. It should be noted that the optical module is a tool to achieve the conversion between optical signals and electrical signals. In the conversion between the optical signals and the electrical signals, the information remains unchanged, and the encoding and decoding methods for the information may vary.

In addition to the optical network unit, the host computer 100 further includes an optical line terminal (OLT), an optical network terminal (ONT), or a data center server.

FIG. 2 is a partial structural diagram of a host computer according to some embodiments of the present disclosure. To clearly show the connection relationship between the optical module 200 and the host computer 100, FIG. 2 shows only the structure of the host computer 100 related to the optical module 200. As shown in FIG. 2, the host computer 100 further includes a printed circuit board (PCB) 105 disposed in the shell, a cage 106 disposed on the surface of the PCB 105, a heat sink 107 disposed on the cage 106, and an electrical connector disposed inside the cage 106. The electrical connector is configured to be connected to the electrical port of the optical module 200. The heat sink 107 has protruding structures such as fins that enlarge the heat dissipation area.

The optical module 200 is inserted into the cage 106 of the host computer 100, and the optical module 200 is fixed by the cage 106. The heat generated by the optical module 200 is conducted to the cage 106 and then diffused through the heat sink 107. After the optical module 200 is inserted into the cage 106, the electrical port of the optical module 200 is connected to the electrical connector inside the cage 106, such that the optical module 200 establishes a two-way electrical signal connection with the host computer 100. In addition, the optical port of the optical module 200 is connected to the optical fiber 101, such that the optical module 200 establishes a two-way optical signal connection with the optical fiber 101.

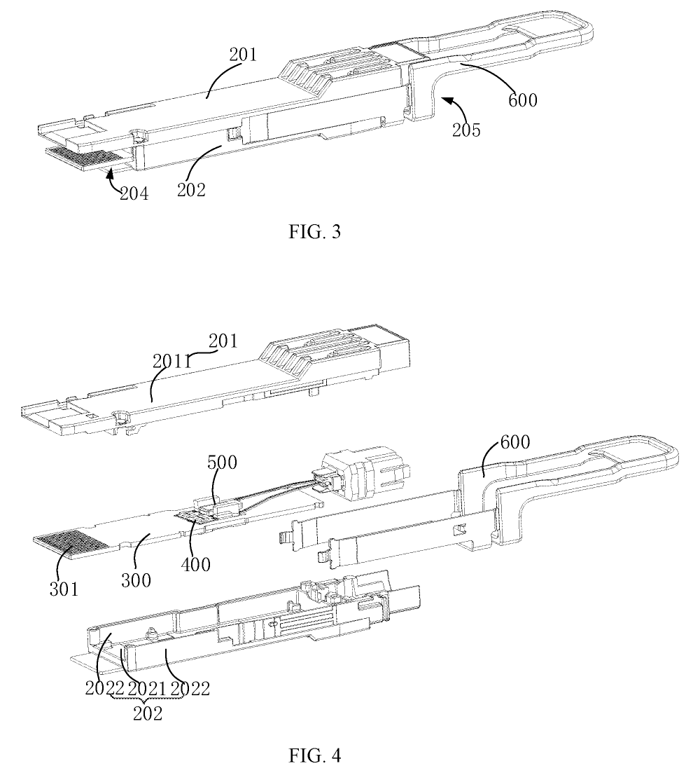

FIG. 3 is a structural diagram of an optical module according to some embodiments of the present disclosure. FIG. 4 is an exploded view of an optical module according to some embodiments of the present disclosure. As shown in FIG. 3 and FIG. 4, the optical module 200 includes a shell, and a circuit board 300, an optical chip 400, and a light source 500 that are disposed in the shell. For example, both the optical chip 400 and the light source 500 are electrically connected to the circuit board 300, and the light output end of the light source 500 is optically coupled to the optical chip 400. In some embodiments, the light output end of the light source 500 is coupled to the optical chip 400 via the optical fiber.

The shell includes an upper shell 201 and a lower shell 202, where the upper shell 201 covers the lower shell 202 to form the shell with an opening 204 and an opening 205; and the outer contour of the shell is generally square.

In some embodiments, the lower shell 202 includes a bottom plate 2021 and two lower side plates 2022 located at two sides of the bottom plate 2021 and perpendicular to the bottom plate 2021; and the upper shell 201 includes a cover plate 2011, where the cover plate 2011 covers the two lower side plates 2022 of the lower shell 202 to form the shell.

In some embodiments, the lower shell 202 includes a bottom plate 2021 and two lower side plates 2022 located at two sides of the base plate 2021 and perpendicular to the bottom plate 2021; and the upper shell 201 includes a cover plate 2011 and two upper side plates located at two sides of the cover plate 2011 and perpendicular to the cover plate 2011, where the two upper side plates and the two lower side plates 2022 are combined to ensure that the upper shell 201 covers the lower shell 202.

The direction of a connecting line between the opening 204 and the opening 205 may be consistent with the length direction of the optical module 200 or may be inconsistent with the length direction of the optical module 200. For example, the opening 204 is located at an end of the optical module 200 (the left end of FIG. 3), and the opening 205 is also located at an end of the optical module 200 (the right end of FIG. 3). Alternatively, the opening 204 is located at an end of the optical module 200, and the opening 205 is located on a side of the optical module 200. The opening 204 is an electrical port, where a golden finger 301 of the circuit board 300 extends out from the opening 204 and is inserted into the electrical connector of the host computer 100. The opening 205 is an optical port, which is configured to be connected to the external optical fiber 101 such that the optical fiber 101 is connected to the optical chip 400 in the optical module 200.

An assembly method of combining the upper shell 201 with the lower shell 202 is adopted, such that the circuit board 300, the optical modulation chip 900, the light source 1100, and other components can be conveniently mounted in the shell, and these components can be packaged by the upper shell 201 and the lower shell 202 for protection. In addition, when the circuit board 300, the optical chip 400, the light source 500 and other components are assembled, it is convenient for deployment of positioning parts, heat dissipation parts and electromagnetic shielding portions of these devices, which is conducive to automatic production.

In some embodiments, the upper shell 201 and the lower shell 202 are made of metal materials, facilitating electromagnetic shielding and heat dissipation.

In some embodiments, the optical module 200 further includes an unlocking component 600 located outside its shell. The unlocking component 600 is configured to achieve a fixed connection between the optical module 200 and the host computer, or to release the fixed connection between the optical module 200 and the host computer.

For example, the unlocking component 600 is located outside the two lower side plates 2022 of the lower shell 202, and includes an engaging component that matches the cage 106 of the host computer 100. When the optical module 200 is inserted into the cage 106, the optical module 200 is fixed in the cage 106 by the clamping component of the unlocking component 600; and when the unlocking component 600 is pulled, the clamping component of the unlocking component 600 moves accordingly, such that the connection relationship between the clamping component and the host computer is changed to release the fixation between the optical module 200 and the host computer, thereby pulling out the optical module 200 from the cage 106.

The circuit board 300 includes circuit traces, electronic components, and chips, where the electronic components and the chips are connected according to the circuit design through the circuit traces to implement the functions such as power supply, electrical signal transmission and grounding. The electronic components may include, for example, capacitors, resistors, transistors, and metal-oxide-semiconductor field-effect transistors (MOSFETs). The chips may include, for example, microcontroller units (MCUs), laser driving chips, transimpedance amplifiers (TIAs), limiting amplifiers (LAs), clock and data recovery (CDR) chips, power management chips, and digital signal processing (DSP) chips.

The circuit board 300 is generally a rigid circuit board. The rigid circuit board can also achieve the bearing effect because of its relatively hard material, for example, the rigid circuit board can smoothly carry the above-mentioned electronic components and chips. The rigid circuit board can also be inserted into the electrical connector in the cage 106 of the host computer 100.

The circuit board 300 further includes golden fingers 301 formed on the end surface thereof, where each golden finger 301 includes a plurality of independent pins. The circuit board 300 is inserted into the cage 106, and the golden fingers 301 are connected to the electrical connector in the cage 106. The golden finger 301 may be arranged only on the surface of a side of the circuit board 300 (for example, the upper surface shown in FIG. 4), or may be arranged on the surfaces of the upper and lower sides of the circuit board 300 to provide more pins, so as to adapt to the occasion where a large number of pins are required. The golden finger 301 is configured to establish an electrical connection with the host computer to achieve power supply, grounding, two-wire inter-integrated circuit (I2C) signal transmission, data signal transmission, etc. Certainly, flexible circuit boards are also used in some optical modules. Flexible circuit boards are generally used in conjunction with rigid circuit boards as a supplement to rigid circuit boards.

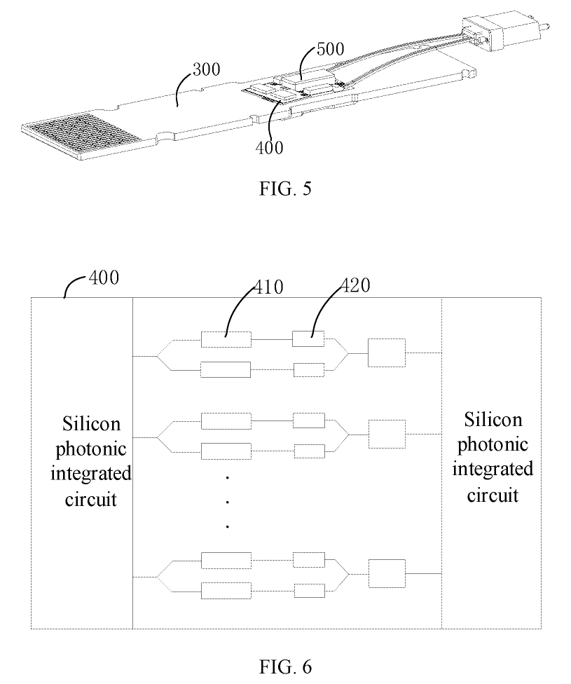

FIG. 5 is a schematic diagram of an internal structure of an optical module according to some embodiments of the present disclosure. As shown in FIG. 5, in some embodiments, the light source 500 is provided at a side of the optical chip 400, and the light emitted from the side surface of the light source 500 is coupled into the optical chip 400. The light source 500 serves as an external light source for the optical chip 400, and the light emitted by the light source 500 enters the optical chip 400. The light source 500 may be a laser box, in which a laser is encapsulated. The laser emits light to generate a laser beam, and the light source 500 is used to provide the emitted laser to the optical chip 400. Laser has become the preferred light source for optical modules and even optical fiber transmission due to its excellent single-wavelength characteristics and optimal wavelength tuning characteristics. Other types of light, such as LED light, are generally not adopted in common optical communication systems. Even if such light sources are used in special optical communication systems, their characteristics and chip components differ significantly from those of lasers, resulting in substantial technical differences between optical modules using lasers and optical modules using other light sources. Those skilled in the art generally would not consider these two types of optical modules to be technically interchangeable.

The light emitted by the light source 500 is non-data-carrying light that is light to be modulated. The light to be modulated enters the optical chip 400, and the optical chip 400 performs phase modulation on the light to load the electrical signal onto the light, so as to obtain data-carrying light, namely, an optical emission signal, thereby implementing emission of the optical signal; likewise, external light enters the optical chip 400, and the optical chip 400 demodulates the external light, thereby implementing reception of the optical signal.

In some embodiments, the optical chip 400 may be a silicon photonic chip, that is, the optical chip 400 is formed by packaging with a silicon material. The silicon photonic chip includes a Mach-Zehnder modulator (MZM), within which a silicon photonic phase modulator is integrated. The silicon photonic phase modulator is configured to modulate and demodulate optical signals. Since the silicon photonic chip is easy to etch, other functional devices such as beam splitters, beam combiners, frequency mixers, and photodetectors can be integrated inside the silicon photonic chip, thereby implementing more functions.

FIG. 6 is a schematic layout diagram of a silicon photonic chip according to some embodiments of the present disclosure. As shown in FIG. 6, multiple channels are integrated inside the silicon photonic chip. Each channel includes a silicon photonic phase modulator 410, a thermal phase shifter 420, and the like. The silicon photonic phase modulator 410, the thermal phase shifter 420, and the like are respectively formed by packaging with a silicon material, and are interconnected by silicon waveguides.

However, fundamental characteristics of the silicon material result in defects in implementation of optical modulators, such as relatively low modulation efficiency, large capacitance, limited bandwidth, and high optical loss. Therefore, since the silicon photonic phase modulator operates based on carriers, in current long-distance 400 G optical modules, the transmission rate per channel can only reach 50-60 Gbaud. In next-generation optical modules for PAM short-distance transmission at 1.6-3.2 T and coherent long-distance transmission at 800 G-3.2 T, the transmission rate per channel in the optical module needs to exceed 100 Gbaud, and thus the modulation rate of the silicon photonic phase modulator needs to exceed 100 Gbaud. When the modulation rate of the silicon photonic phase modulator is close to 100 Gbaud, an output voltage swing of the driver is relatively high, resulting in high power consumption of the driver.

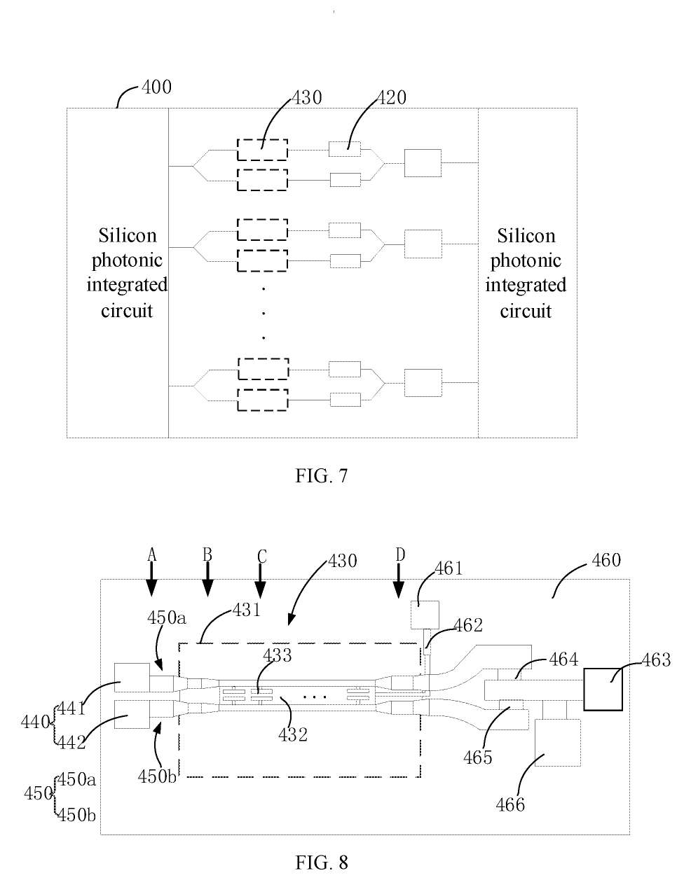

In some embodiments, the optical chip 400 may be a hybrid InP/Si optical chip, that is, the optical chip 400 is formed by hybrid packaging with a silicon material and an InP material. FIG. 7 is a schematic layout diagram of a hybrid InP/Si optical chip according to some embodiments of the present disclosure. As shown in FIG. 7, the hybrid InP/Si optical chip includes multiple channels. Each channel includes an InP phase modulator 430, the thermal phase shifter 420, and the like. The InP phase modulator 430 is formed by packaging with the InP material, the thermal phase shifter 420 is formed by packaging with the silicon material, and the InP phase modulator 430 and the thermal phase shifter 420 are interconnected by silicon waveguides to form a high traveling wave MZM. The hybrid InP/Si optical chip provided in the embodiments of the present disclosure implements hybrid integration of the Si material and the InP material, so as to utilize the InP material to provide high-rate modulation and the Si material to provide highly integrated silicon photonic circuits. As a result, the optical chip 400 can have the high-rate modulation characteristics of the InP material and meet requirements of high‑baud‑rate modulation.

In some embodiments, the hybrid InP/Si optical chip is formed by bonding an InP platform made of the InP material with an Si platform made of the Si material. An InP phase modulator is fabricated on the bonded InP platform, and the silicon photonic circuit is formed on the bonded Si platform. However, a large coefficient of thermal expansion (CTE) mismatch typically exists between the InP platform and the Si platform, resulting in thermal stress concentration. Moreover, an InP-based material is a brittle material, and any mechanical or thermal stress causes reliability problems in terms of temperature and aging, which is not conducive to use of hybrid InP/Si optical chips.

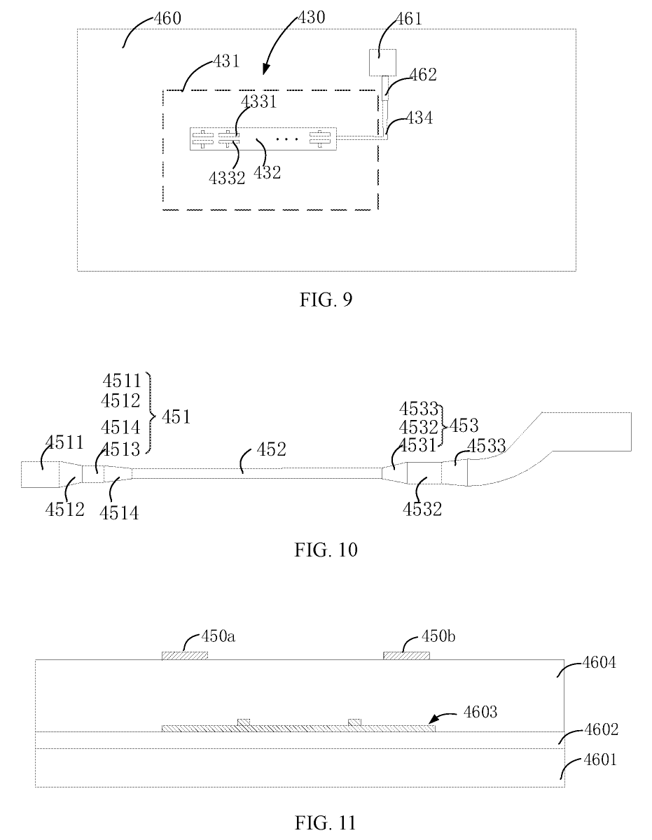

FIG. 8 is a first partial structural diagram of a hybrid InP/Si optical chip according to some embodiments of the present disclosure. FIG. 9 is a second partial structural diagram of a hybrid InP/Si optical chip according to some embodiments of the present disclosure. FIG. 8 and FIG. 9 show a structure of an InP phase modulator 430 in a hybrid InP/Si optical chip. As shown in FIG. 8 and FIG. 9, the hybrid InP/Si optical chip includes an InP region 431 and an Si platform 460, where the InP region 431 is located within the Si platform 460, such that the Si platform 460 encapsulates the InP region 431 from the front, rear, left, right, and bottom of the InP region 431. An InP waveguide 432 is disposed within the InP region 431; and the InP waveguide 432 extends from one end of the InP region 431 to the other end of the InP region 431. A radio frequency pad 440 is disposed on one side of the InP region 431, and is located on the top of the Si platform 460, that is, the radio frequency pad 440 is located outside the InP region 431. The radio frequency pad 440 is configured to electrically connect to a driver to input a radio frequency electrical signal.

In some embodiments, when the hybrid InP/Si optical chip includes multiple channels, the InP/Si optical chip is provided with multiple pairs of InP phase modulators 430 having a structural shape shown in FIG. 8 and FIG. 9. For example, multiple pairs of InP phase modulators 430 are arranged side by side.

In some embodiments, the radio frequency pad 440 includes a first radio frequency pad 441 and a second radio frequency pad 442, where both the first radio frequency pad 441 and the second radio frequency pad 442 are located outside the InP region 431, the first radio frequency pad 441 and the second radio frequency pad 442 are insulated from each other, between which there is a gap. For example, the first radio frequency pad 441 and the second radio frequency pad 442 are arranged side by side on one side of the InP region 431.

A radio frequency traveling waveguide 450 is disposed on the top of the hybrid InP/Si optical chip, where one end of the radio frequency traveling waveguide 450 is connected to the radio frequency pad 440, and the radio frequency traveling waveguide 450 extends over the InP waveguide 432, and spans the InP region 431 to the other side of the InP region 431. The radio frequency traveling waveguide 450 is configured to transmit radio frequency electrical signals, so as to transmit the radio frequency electrical signals input via the radio frequency pad 440 to a position above the InP waveguide 432. For example, a width of the radio frequency traveling waveguide 450 is smaller than a width of the radio frequency pad 440.

In some embodiments, the radio frequency traveling waveguide 450 includes a first radio frequency electrode 450a and a second radio frequency electrode 450b, where the first radio frequency electrode 450a spans the InP region 431 along one side of the top of the InP waveguide 432, and the second radio frequency electrode 450b spans the InP region 431 along the other side of the top of the InP waveguide 432. The first radio frequency electrode 450a extends from one side outside the InP region 431 to the other side outside the InP region 431, and one end of the first radio frequency electrode 450a is connected to the first radio frequency pad 441. The second radio frequency electrode 450b extends from one side outside the InP region 431 to the other side outside the InP region 431, and one end of the second radio frequency electrode 450b is connected to the second radio frequency pad 442.

In some embodiments, a middle portion of the first radio frequency electrode 450a is located on one side of a top edge of the InP waveguide 432, and a middle portion of the second radio frequency electrode 450b is located on the other side of a top edge of the InP waveguide 432.

In some embodiments, a coupling electrode 433 is disposed above the InP waveguide 432, where the coupling electrodes 433 are disposed in pairs and are electrically connected to the radio frequency traveling waveguide 450, and the paired coupling electrodes 433 are configured to couple the radio frequency electrical signals transmitted via the radio frequency traveling waveguide 450 above the InP waveguide 432 into the InP waveguide 432. For example, multiple pairs of coupling electrodes 433 are disposed above the InP waveguide 432, the multiple pairs of coupling electrodes 433 are arranged from one end of the InP waveguide 432 to the other end thereof, each pair of coupling electrodes 433 is respectively connected to the radio frequency traveling waveguide 450, and there is a gap between adjacent pairs of coupling electrodes 433.

In some embodiments, each pair of coupling electrodes 433 is disposed between the first radio frequency electrode 450a and the second radio frequency electrode 450b, where one electrode in each pair of coupling electrodes 433 is electrically connected to the first radio frequency electrode 450a and the other electrode in each pair of coupling electrodes 433 is electrically connected to the second radio frequency electrode 450b, and there is a gap between the two electrodes in each pair of coupling electrodes 433.

In some embodiments, each pair of coupling electrodes 433 comprises a first electrode 4331 and a second electrode 4332, where the first electrode 4331 and the second electrode 4332 are both "T"-shaped electrodes, the first electrode 4331 and the second electrode 4332 are disposed above the InP waveguide 432, tops of the first electrode 4331 and the second electrode 4332 are disposed opposite to each other with a gap therebetween, a bottom of the first electrode 4331 is electrically connected to the first radio frequency electrode 450a, and a bottom of the second electrode 4332 is electrically connected to the second radio frequency electrode 450b. A pair of "T"-shaped electrodes including the first electrode 4331 and the second electrode 4332 is disposed above the InP waveguide 432, and configured to slow down a microwave of the radio frequency electrical signal, thereby facilitating coupling the radio frequency electrical signal into the InP waveguide 432.

In the InP phase modulator 430, a single InP-MQW optical waveguide can achieve high-rate modulation efficiency with an excellent quantum-confined Stark effect, thereby enabling the InP-based traveling waveguide MZM to achieve high bandwidth and meet requirements for high data rates in optical modules.

A direct current bias pad 461 is further disposed outside the InP region 431, where the direct current bias pad 461 is located on the Si platform 460, the direct current bias pad 461 is electrically connected to the InP waveguide 432, and configured to provide a bias current to a PN junction in the InP waveguide 432. For example, a connecting waveguide 434 and a bias input electrode 462 are disposed on the other side of the InP waveguide 432, where the bias input electrode 462 is located outside the InP region 431, the connecting waveguide 434 is made of an InP material, a portion of the connecting waveguide 434 is located inside the InP region 431 and another portion thereof is located outside the InP region 431. One end of the connecting waveguide 434 is connected to the InP waveguide 432, the other end of the connecting waveguide 434 is connected to one end of the bias input electrode 462, and the other end of the bias input electrode 462 is connected to the direct current bias pad 461. A width of the bias input electrode 462 is smaller than a width of the direct current bias pad 461, and the bias input electrode 462 is configured to implement a transition connection from the direct current bias pad 461 to the connecting waveguide 434. The bias input electrode 462 couples a bias current input through the direct current bias pad 461 to the connecting waveguide 434, and the bias current is loaded to the InP waveguide 432 through the connecting waveguide 434; and the bias input electrode 462 is located on the Si platform 460, and the connecting waveguide 434 extends from the InP region 431 to the Si platform 460.

In some embodiments, the connecting waveguide 434 extends to the Si platform 460 along a length direction of the InP waveguide 432, and then extends within the Si platform 460 toward a direction in which the direct current bias pad 461 is located. Of course, in order to reasonably arrange components on the Si platform 460, the direct current bias pad 461 may be disposed at a position perpendicular to a length direction of the InP waveguide 432. After the connecting waveguide 434 extends to a position on the Si platform 460 corresponding to the direct current bias pad 461, the connecting waveguide 434 may turn 90° and further extend until the connecting waveguide 434 is connected to the bias input electrode 462.

In some embodiments, a terminal pad 463 is disposed outside the InP region 431, and the terminal pad 463 is connected to the other end of the radio frequency traveling waveguide 450. In some embodiments, the terminal pad 463 is connected to the first radio frequency electrode 450a and the second radio frequency electrode 450b, such that the first radio frequency electrode 450a and the second radio frequency electrode 450b form a closed loop.

In the embodiments of the present disclosure, the InP region 431 is a forbidden region in the hybrid circuit layout of the hybrid InP/Si optical chip. No pads or other devices requiring bonding are disposed inside the InP region 431, so as to avoid any stress caused by bonding, mechanical and thermal effects, and to eliminate problems such as temperature and aging.

FIG. 10 is a schematic structural diagram of a first radio frequency electrode according to some embodiments of the present disclosure, and FIG. 10 shows a structural form of a first radio frequency electrode. As shown in FIG. 10, the first radio frequency electrode 450a includes a parallel section 452, where the parallel section 452 is disposed on one side of an upper edge of the InP waveguide 432, a side of the parallel section 452 is connected to a bottom of the coupling electrode 433, and the parallel section 452 facilitates coupling and transmitting the radio frequency electrical signal to each coupling electrode 433, such that the radio frequency electrical signal is passively coupled to the InP waveguide 432 through each coupling electrode 433. For example, a width of the parallel section 452 is smaller than a width of the first radio frequency pad 441, and the parallel section 452 is a straight and narrow strip structure.

In some embodiments, the first radio frequency electrode 450a includes a first connecting section 451 and a second connecting section 453, where one end of the parallel section 452 is connected to the first connecting section 451, and the other end of the parallel section 452 is connected to the second connecting section 453. One end of the first connecting section 451 is connected to the first radio frequency pad 441, the other end of the first connecting section 451 is connected to one end of the parallel section 452, and the first connecting section 451 is configured to implement transition from the first radio frequency pad 441 to the radio frequency traveling waveguide of the parallel section 452. One end of the second connecting section 453 is connected to the other end of the parallel section 452, the other end of the second connecting section 453 is connected to the terminal pad 463, and the second connecting section 453 is configured to implement transition from the parallel section 452 to a tail end of the first radio frequency electrode 450a. The first radio frequency electrode 450a is configured to adapt to a difference between a dielectric constant of InP and a dielectric constant of SiO₂ in the Si platform 460, thereby ensuring integrity of signals having a transmission rate greater than 100 Gbaud.

In some embodiments, the first connecting section 451 includes a first transition region 4512, where a width of one end of the first transition region 4512 is greater than a width of the other end of the first transition region 4512. The first transition region 4512 is configured to adjust a width of one end of the first radio frequency electrode 450a, and the first transition region 4512 facilitates coupling and transmitting the radio frequency electrical signal from the radio frequency pad to the radio frequency traveling waveguide 450. For example, a width of the first transition region 4512 gradually decreases from one end to the other end. In other words, a width of one end of the first transition region 4512 facing the first radio frequency pad 441 is greater than a width of one end of the first transition region 4512 facing the parallel section 452.

In some embodiments, the first connecting section 451 includes a second transition region 4514, where a width of one end of the second transition region 4514 is greater than a width of the other end of the second transition region 4514. The second transition region 4514 is configured to implement width transition from the first radio frequency electrode 450a to the parallel section 452, and the second transition region 4514 facilitates coupling and transmitting the radio frequency electrical signal from the radio frequency pad to the radio frequency traveling waveguide. For example, a width of the second transition region 4514 gradually decreases from one end to the other end. In other words, a width of one end of the second transition region 4514 facing the first radio frequency pad 441 is greater than a width of one end of the second transition region 4514 facing the parallel section 452.

In some embodiments, the first connecting section 451 includes a first connecting region 4511, where one end of the first connecting region 4511 is connected to the first radio frequency pad 441, the other end of the first connecting region 4511 is connected to one end of the first transition region 4512, and the first connecting region 4511 is configured to facilitate connection of the first transition region 4512 to the first radio frequency pad 441.

In some embodiments, the first connecting section 451 includes a second connecting region 4513, where the second connecting region 4513 is connected to one end of the second transition region 4514, and the second connecting region 4513 is configured to facilitate connection of the second transition region 4514 to the first transition region 4512.

In some embodiments, the first connecting section 451 includes the first connecting region 4511, the first transition region 4512, the second connecting region 4513, and the second transition region 4514. One end of the first connecting region 4511 is connected to the first radio frequency pad 441, the other end of the first connecting region 4511 is connected to one end of the first transition region 4512, the other end of the first transition region 4512 is connected to one end of the second connecting region 4513, the other end of the second connecting region 4513 is connected to one end of the second transition region 4514, and one end of the second transition region 4514 is connected to one end of the parallel section 452. The width of one end of the first transition region 4512 is greater than the width of the other end of the first transition region 4512, and the width of the first transition region 4512 gradually changes from one end to the other end; and the width of one end of the second transition region 4514 is greater than the width of the other end of the second transition region 4514, and the width of the second transition region 4514 gradually changes from one end to the other end. The first connecting region 4511 is located above the Si platform 460; one end of the first transition region 4512 is located above the Si platform 460, and the other end of the first transition region 4512 is located above the InP region 431; and the second connecting region 4513 and the second transition region 4514 are located above the InP region 431.

In some embodiments, the second connecting section 453 includes a third transition region 4531, where a width of one end of the third transition region 4531 is smaller than a width of the other end of the third transition region 4531, and one end of the third transition region 4531 is connected to the other end of the parallel section 452. The third transition region 4531 is configured to implement adjustment of the width from the parallel section 452 to the other end of the first radio frequency electrode 450a, so as to facilitate adjustment of the width of the other end of the first radio frequency electrode 450a and to ensure coupling and transmission performance of the radio frequency electrical signal to the radio frequency traveling waveguide. For example, a width of the third transition region 4531 gradually increases from one end to the other end.

In some embodiments, the second connecting section 453 includes a fourth transition region 4533, where a width of one end of the fourth transition region 4533 is smaller than a width of the other end of the fourth transition region 4533. The fourth transition region 45331 is configured to implement adjustment of the width from the parallel section 452 to the other end of the first radio frequency electrode 450a, so as to facilitate adjustment of the width of the other end of the first radio frequency electrode 450a and to ensure coupling and transmission performance of the radio frequency electrical signal to the radio frequency traveling waveguide. For example, the width of the fourth transition region 4533 gradually increases from one end to the other end.

In some embodiments, the second connecting section 453 includes the third transition region 4531, a third connecting region 4532, and the fourth transition region 4533. One end of the third transition region 4531 is connected to the other end of the parallel section 452, the other end of the third transition region 4531 is connected to one end of the third connecting region 4532, and the other end of the third connecting region 4532 is connected to one end of the fourth transition region 4533. The width of one end of the third transition region 4531 is smaller than the width of the other end of the third transition region 4531, and the width of the third transition region 4531 gradually changes from one end to the other end; and the width of one end of the fourth transition region 4533 is less than the width of the other end of the fourth transition region 4533, and the width of the fourth transition region 4533 gradually changes from one end to the other end. The third transition region 4531 and the third connecting region 4532 are located above the InP region 431, one end of the fourth transition region 4533 is located above the InP region 431, and the other end of the fourth transition region 4533 is located above the Si platform 460.

In some embodiments, a structural form of the second radio frequency electrode 450b is the same as or similar to a structural form of the first radio frequency electrode 450a. For example, the second radio frequency electrode 450b and the first radio frequency electrode 450a are symmetrically disposed at an edge above the InP waveguide 432. Portions of the first radio frequency electrode 450a and the second radio frequency electrode 450b extending from the Si platform 460 to the InP region 431 undergo a gradual morphological change, which facilitates adaptation to the InP waveguide 432 with and without PN junctions, and is critical to ensuring a modulation rate of the phase modulator.

In some embodiments, the hybrid InP/Si optical chip further includes a first resistor 464, where the first resistor 464 is located outside the InP region 431. One end of the first resistor 464 is electrically connected to the other end of the first radio frequency electrode 450a, the other end of the first resistor 464 is electrically connected to the terminal pad 463, and the first resistor 464 is configured to match impedance of a transmission circuit on the first radio frequency electrode 450a. For example, the first resistor 464 is an on-chip resistor.

In some embodiments, the hybrid InP/Si optical chip further includes a second resistor 465, where the second resistor 465 is located outside the InP region 431. One end of the second resistor 465 is electrically connected to the second radio frequency electrode 450b, the other end of the second resistor 465 is electrically connected to the terminal pad 463, and the second resistor 465 is configured to match impedance of a transmission circuit on the second radio frequency electrode 450b. For example, the second resistor 465 is an on-chip resistor.

In some embodiments, the hybrid InP/Si optical chip further includes a first resistor 464, a second resistor 465, and a capacitor 466, where the first resistor 464 and the second resistor 465 are on-chip resistors, and the capacitor 466 is an on-chip capacitor. One end of the first resistor 464 is electrically connected to the other end of the first radio frequency electrode 450a, and the other end of the first resistor 464 is electrically connected to the terminal pad 463; one end of the second resistor 465 is electrically connected to the second radio frequency electrode 450b, and the other end of the second resistor 465 is electrically connected to the terminal pad 463; and one end of the capacitor 466 is connected between the other end of the first resistor 464 and the other end of the second resistor 465, and the other end of the capacitor 466 is grounded. The first resistor 464, the second resistor 465, and the capacitor 466 form a matching circuit, and are configured to match the transmission circuits of the first radio frequency electrode 450a and the second radio frequency electrode 450b, thereby ensuring performance of coupling radio frequency electrical signals from the first radio frequency electrode 450a and the second radio frequency electrode 450b to the InP waveguide 432. The first resistor 464, the second resistor 465, and the capacitor 466 are located outside the InP region 431, which can effectively reduce adverse effects of the InP waveguide 432 caused by mechanical stress, thermal stress, and the like generated by disposition of the first resistor 464, the second resistor 465, and the capacitor 466.

In some embodiments, the first resistor 464 and the second resistor 465 are disposed between the other end of the first radio frequency electrode 450a and the other end of the second radio frequency electrode 450b. A distance between the other end of the first radio frequency electrode 450a and the other end of the second radio frequency electrode 450b is greater than a distance between one end of the first radio frequency electrode 450a and one end of the second radio frequency electrode 450b, which facilitates disposition of the first resistor 464 and the second resistor 465.

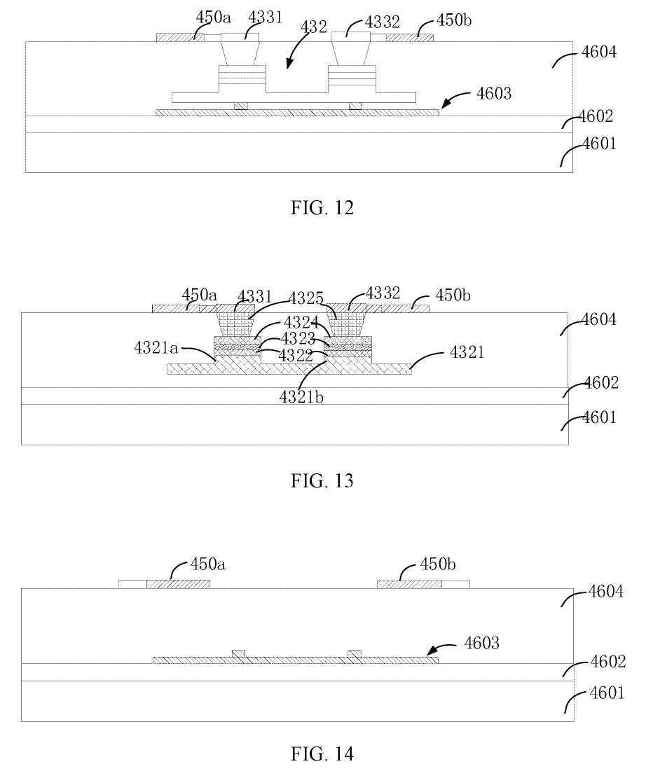

FIG. 11 is a first enlarged sectional view of a hybrid InP/Si optical chip according to some embodiments of the present disclosure. FIG. 12 is a second enlarged sectional view of a hybrid InP/Si optical chip according to some embodiments of the present disclosure. FIG. 13 is a third enlarged sectional view of a hybrid InP/Si optical chip according to some embodiments of the present disclosure. FIG. 14 is a fourth enlarged sectional view of a hybrid InP/Si optical chip according to some embodiments of the present disclosure. FIG. 11 shows a cross-sectional structure at a position A in FIG. 8. FIG. 12 shows a cross-sectional structure at a position B in FIG. 8. FIG. 13 shows a cross-sectional structure at a position C in FIG. 8. FIG. 14 shows a cross-sectional structure at a position D in FIG. 8. FIG. 11 shows a cross-sectional structure of a hybrid InP/Si optical chip outside an InP region, where the cross section does not intersect the InP region; FIG. 12 shows a cross-sectional structure of a hybrid InP/Si optical chip at an edge of one end of the InP waveguide, where the cross section intersects the InP region but not the InP waveguide; FIG. 13 shows a cross-sectional structure of a hybrid InP/Si optical chip on the InP waveguide, where the cross section intersects the InP waveguide; FIG. 14 shows a structure of a hybrid InP/Si optical chip outside the other end of the InP waveguide, where the cross section does not intersect the InP waveguide; and FIG. 11 to FIG. 13 show a main cross-sectional structure of an InP phase modulator 430 in details.

As shown in FIG. 11, the Si platform 460 includes a substrate layer 4601, a BOX layer 4602 is disposed above the substrate layer 4601, an Si waveguide layer 4603 and an SiO₂ layer 4604 are disposed above the BOX layer 4602, the Si waveguide layer 4603 is encapsulated by the SiO₂ layer 4604, the Si waveguide layer 4603 includes a strip-shaped Si waveguide, and a top of the SiO₂ layer 4604 supports the first radio frequency electrode 450a and the second radio frequency electrode 450b. The Si waveguide in the Si waveguide layer 4603 includes an optical input Si waveguide, where the optical input Si waveguide is configured to input light. For example, the substrate layer 4601 is formed by epitaxial growth of the Si material, and the BOX layer 4602 is formed by epitaxial growth of the SiO₂ material.

In some embodiments, a cross section of the optical input Si waveguide is a "convex" structure, that is, the size of the top of the optical input Si waveguide is smaller than the size of the bottom of the optical input Si waveguide, which facilitates coupling the light input through the optical input Si waveguide into the InP waveguide 432.

As shown in FIG. 12, the InP waveguide 432 is embedded in the SiO₂ layer 4604, and the Si waveguide in the Si waveguide layer 4603 extends to a position below one end of the InP waveguide 432. The Si waveguide layer 4603 is configured to transmit light to one end of the InP waveguide 432 and couple the light into the InP waveguide 432.

As shown in FIG. 12 and FIG. 13, the InP waveguide 432 includes an n-InP layer 4321, and a first n-InP protrusion 4321a and a second n-InP protrusion 4321b are disposed on a top of the n-InP layer 4321. A gap is provided between the first n-InP protrusion 4321a and the second n-InP protrusion 4321b. A first i-InP layer 4322, a quantum well (QW) layer 4323, a second i-InP layer 4324, and a p-InP layer 4325 are sequentially disposed above the first n-InP protrusion 4321a; a first i-InP layer 4322, a quantum well (QW) layer 4323, a second i-InP layer 4324, and a p-InP layer 4325 are sequentially disposed above the second n-InP protrusion 4321b. A coupling electrode 433 is disposed above the p-InP layer 4325. For example, a first electrode 4331 is disposed on the p-InP layer 4325 above the first n-InP protrusion 4321a, and a second electrode 4332 is disposed on the p-InP layer 4325 above the second n-InP protrusion 4321b. A gap between the first i-InP layer 4322, the quantum well (QW) layer 4323, the second i-InP layer 4324, and the p-InP layer 4325 above the first n-InP protrusion 4321a and the second n-InP protrusion 4321b is filled with the SiO₂ material, such that the InP waveguide 432 is encapsulated by the SiO₂ layer 4604, forming two elongated waveguide structures.

In some embodiments, the first radio frequency electrode 450a is located on one side of the first electrode 4331 away from the second electrode 4332, and the second radio frequency electrode 450b is located on one side of the second electrode 4332 away from the first electrode 4331. The first radio frequency electrode 450a is connected to the first electrode 4331, and the second radio frequency electrode 450b is connected to the second electrode 4332.

In some embodiments, the radio frequency electrical signals transmitted via the first radio frequency electrode 450a and the second radio frequency electrode 450b are coupled into the InP waveguide 432 via the first electrode 4331 and the second electrode 4332. The InP waveguide 432 forms a PN junction, and under an electric field generated by the radio frequency electrical signal, a carrier phase changes, thereby changing a refractive index of the optical wave coupled from the Si waveguide into the InP waveguide 432 to change the phase of the optical wave and implement modulation of the optical wave.

As shown in FIG. 14, an Si waveguide layer 4603 is disposed below the other end of the InP waveguide 432, and the Si waveguide layer 4603 includes the strip-shaped Si waveguide. The Si waveguide in the Si waveguide layer 4603 includes an optical output Si waveguide, where the optical output Si waveguide extends from a position below the other end of the InP waveguide 432 in a direction away from the InP waveguide 432. The optical wave modulated by the InP waveguide 432 is coupled into the Si waveguide in the Si waveguide layer 4603 for transmission via the Si waveguide.

In some embodiments, a cross section of the optical output Si waveguide in the Si waveguide layer 4603 is a "convex" structure, that is, the size of the top of the optical output Si waveguide is smaller than the size of the bottom of the optical output Si waveguide, which facilitates coupling light modulated by the InP waveguide 432 into the optical output Si waveguide.

In some embodiments of the present application, when the hybrid InP/Si optical chip is fabricated, the Si platform 460 is fabricated, and a groove is formed in the Si platform 460; an InP material including the n-InP layer 4321, the first i-InP layer 4322, the quantum well layer 4323, the second i-InP layer 4324, and the p-InP layer 4325 is placed in the groove, and the InP material is processed to form the InP waveguide 432; the SiO₂ material is filled around the InP waveguide 432, such that the InP waveguide 432 is encapsulated by a continuous SiO₂ layer 4604; and a coupling electrode 433 is formed on the top of the InP waveguide 432, and a first radio frequency electrode 450a and a second radio frequency electrode 450b are formed on the SiO₂ layer 4604.

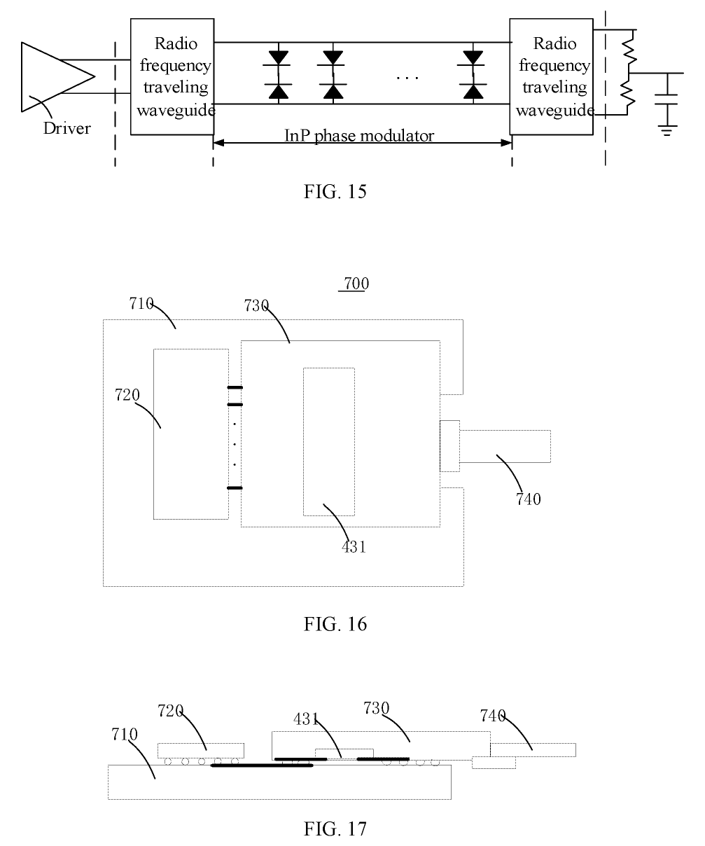

FIG. 15 is an equivalent circuit diagram of a hybrid InP/Si optical chip according to some embodiments of the present disclosure. As shown in FIG. 15, each pair of coupling electrodes 433 and the InP waveguide 432 below each pair of coupling electrodes 433 form a pair of cathode-opposed diodes. In some embodiments, the cathodes of the diode pairs are connected to a bias voltage.

As shown in FIG. 15, in the hybrid InP/Si optical chip provided by the embodiments of the present disclosure, a pad or a similar structure is not disposed in the InP region 431, such that there is a relatively sufficient distance between the pad or the similar structure and the InP waveguide 432. The radio frequency traveling waveguide 450 is used to couple the radio frequency electrical signal into the InP waveguide 432, which can effectively avoid influence of stress caused by bonding pads on the InP waveguide 432 within the InP region 431. This enables use of the InP material on the Si platform, thus improving a modulation rate and reliability of the phase modulator. Moreover, in the hybrid InP/Si optical chip, the InP phase modulator formed by the InP material is of a T-rail traveling waveguide structure and configured to implement high-rate and high-efficiency modulation with phase and impedance matching.

FIG. 16 is a first schematic structural diagram of a hybrid InP/Si optical chip assembly according to some embodiments of the present disclosure. FIG. 17 is a second schematic structural diagram of a hybrid InP/Si optical chip assembly according to some embodiments of the present disclosure. FIG. 16 and FIG. 17 show an external structure of a hybrid InP/Si optical chip assembly. As shown in FIG. 16 and FIG. 17, the hybrid InP/Si optical chip assembly 700 includes a substrate 710, a driver 720 and a hybrid InP/Si optical chip 730 are disposed above the substrate 710, and an optical fiber assembly 740 is connected to a side of the hybrid InP/Si optical chip 730. The driver 720 and the hybrid InP/Si optical chip 730 are each connected to the substrate 710 by soldering. The driver 720 is electrically connected to the hybrid InP/Si optical chip 730 via a high-frequency transmission line on the substrate 710. The hybrid InP/Si optical chip 730 is the hybrid InP/Si optical chip provided in the above embodiments, where the InP material is disposed inside the Si platform to form an InP phase modulator. For example, the driver 720 and the hybrid InP/Si optical chip 730 are each connected to the substrate by a solder ball. One end of the high-frequency transmission line on the substrate 710 is connected to the driver 720, and the other end thereof is connected to the radio frequency pad on the hybrid InP/Si optical chip.

In the hybrid InP/Si optical chip assembly provided by the embodiments of the present disclosure, bonding and termination structures of the hybrid InP/Si optical chip are both disposed outside the InP phase modulator, which helps reduce influence of mechanical stress and thermal stress on the InP phase modulator. The optical fiber assembly 740 is also disposed outside the InP phase modulator, eliminating stress generated by connecting the optical fiber assembly 740 and further reducing influence of connecting the optical fiber assembly 740 on the InP phase modulator. The hybrid InP/Si optical chip assembly can be used in the optical module.

In some embodiments, other devices made of the InP material, such as lasers and semiconductor optical amplifiers (SOA), may also be disposed in the hybrid InP/Si optical chip assembly. The lasers, the semiconductor optical amplifiers and the like made of the InP material can be integrated into the InP region in which the InP phase modulator is located, or the InP region outside the InP phase modulator within the Si platform. The specific disposition can refer to disposition of the InP phase modulator within the Si platform, which helps reduce influence of thermal stress and mechanical stress on the corresponding InP region, and facilitates integration of the lasers, the semiconductor optical amplifiers, and other devices made of InP material into the platform.

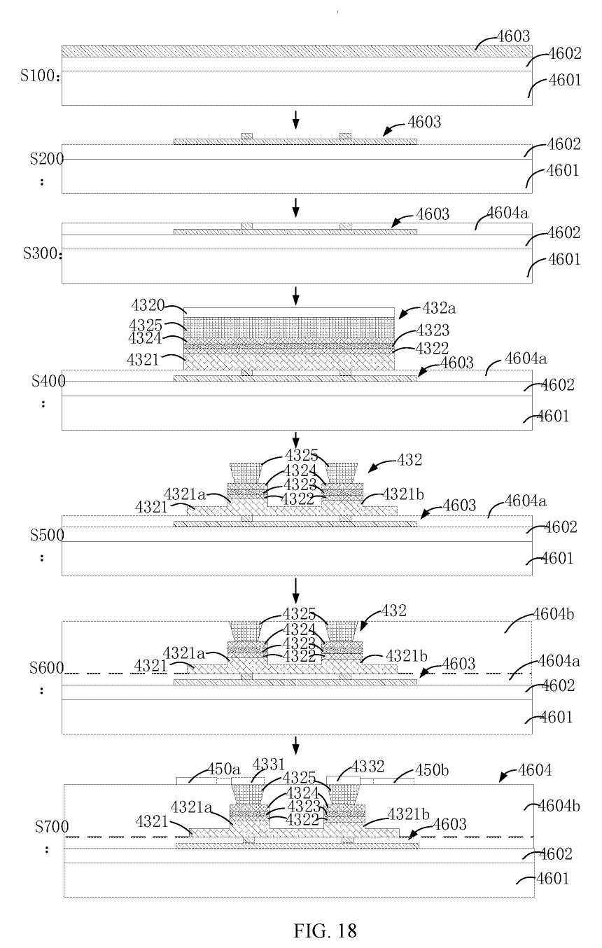

Based on the hybrid InP/Si optical chip provided by the embodiments of the present disclosure, the embodiments of the present disclosure further provide a fabrication method for a hybrid InP/Si optical chip. The fabrication method for a hybrid InP/Si optical chip provided by the embodiments of the present disclosure is used to facilitate fabrication of the hybrid InP/Si optical chip provided in the above embodiments. FIG. 18 is a flowchart of a fabrication method for a hybrid InP/Si optical chip according to some embodiments of the present disclosure. FIG. 18 shows a cross-sectional structure of a hybrid InP/Si optical chip formed at each step. As shown in FIG. 18, a fabrication method for a hybrid InP/Si optical chip according to the embodiments of the present disclosure includes:

S100: form a first substrate, where the first substrate includes a substrate layer and a BOX layer, and the BOX layer is located above the substrate layer.

The substrate layer 4601 is epitaxially grown, and the BOX layer 4602 is grown on the substrate layer 4601. The substrate layer 4601 is formed by epitaxial growth of the Si material, and the BOX layer 4602 is formed by epitaxial growth of the SiO₂ material.

S200: form an Si waveguide layer above the BOX layer, and etch the Si waveguide layer to form an input Si waveguide and an output Si waveguide, where a gap is formed between the input Si waveguide and the output Si waveguide.

The Si waveguide layer 4603 is epitaxially grown on the BOX layer 4602, a Si waveguide pattern is formed on the Si waveguide layer 4603 by masking, and an input Si waveguide and an output Si waveguide are formed by etching. A gap is formed between the input Si waveguide and the output Si waveguide, above which the InP waveguide 432 is disposed. The input Si waveguide is used to input light and transmit the light to the InP waveguide 432; and the output Si waveguide is used to output light and transmit the light output from the InP waveguide 432.

In some embodiments, cross sections of the input Si waveguide and the output Si waveguide are a "convex" structure, that is, the sizes of the tops are smaller than the sizes of the bottoms, and the input Si waveguide and the output Si waveguide can be formed by secondary etching.

S300: form a first SiO₂ layer around the etched Si waveguide layer, where the first SiO₂ layer fills a region that is of the Si waveguide layer and etched away.

The first SiO₂ layer 4604a is epitaxially grown, such that sides of the Si waveguide layer 4603 are encapsulated by the first SiO₂ layer 4604a, and the top of the Si waveguide layer 4603 is exposed.

S400: dispose an InP bare die above the first SiO₂ layer, where the InP bare die includes, from bottom to top, an n-InP layer, a first i-InP layer, a quantum well layer, a second i-InP layer, a p-InP layer, and a second substrate.

The InP bare die 432a is disposed on the first SiO₂ layer 4604a, where the InP bare die covers a gap between the input Si waveguide and the output Si waveguide, and ends of the input Si waveguide and the output Si waveguide are located below an end of the InP bare die 432a.

The InP bare die 432a includes a second substrate 4320; and a p-InP layer 4325, a second i-InP layer 4324, a quantum well layer 4323, a first i-InP layer 4322, and an n-InP layer 4321 are sequentially disposed above the second substrate 4320. The InP bare die 432a is flipped upside down onto the first SiO₂ layer 4604a, such that the n-InP layer contacts a top surface of the first SiO₂ layer 4604a.

In some embodiments, the InP bare die 432a can be formed by sequentially growing a p-InP layer 4325, a second i-InP layer 4324, a quantum well layer 4323, a first i-InP layer 4322, and an n-InP layer 4321 on the second substrate 4320.

S500: etch the InP bare die to form an InP waveguide, where a bottom of the InP waveguide forms a first n-InP protrusion and a second n-InP protrusion on a top of the n-InP layer, a gap is formed between the first n-InP protrusion and the second n-InP protrusion, and a top of the first n-InP protrusion and a top of the second n-InP protrusion respectively support the first i-InP layer, the quantum well layer, the second i-InP layer, and the p-InP layer.

The second substrate 4320 is etched away, and then the InP waveguide 432 is formed by etching. In some embodiments, the InP bare die 432a can be etched to form a single InP waveguide 432 or multiple InP waveguides 432. When the InP bare die 432a is etched to form a single InP waveguide 432, an etching depth reaches the n-InP layer 4321 but does not reach the first SiO₂ layer 4604a, such that the n-InP layer 4321 forms a first n-InP protrusion 4321a and a second n-InP protrusion 4321b, and a gap is formed between the first n-InP protrusion 4321a and the second n-InP protrusion 4321b. The first i-InP layer 4322, the quantum well layer 4323, the second i-InP layer 4324, and the p-InP layer 4325 above the gap are etched away to form a trench that extends deep into the n-InP layer 4321 on the InP bare die 432a. The first i-InP layer 4322, the quantum well layer 4323, the second i-InP layer 4324, and the p-InP layer 4325 above a side of the first n-InP protrusion 4321a and a side of the second n-InP protrusion 4321b that are away from the gap are also etched away, such that the first i-InP layer 4322, the quantum well layer 4323, the second i-InP layer 4324, and the p-InP layer 4325 are still supported and disposed only above the first n-InP protrusion 4321a and above the second n-InP protrusion 4321b. When the InP bare die 432a is etched to form multiple InP waveguides 432, the first SiO₂ layer 4604a is etched between adjacent InP waveguides 432, preventing the adjacent InP waveguides 432 from being connected.

S600: form a second SiO₂ layer on the side of the InP waveguide, where the first SiO₂ layer and the second SiO₂ layer form an SiO₂ layer.

A second SiO₂ layer 4604b is epitaxially grown, such that the second SiO₂ layer 4604b is included on the side of the InP waveguide 432 and is filled above the first n-InP protrusion 4321a and inside the second n-InP protrusion 4321b. The first SiO₂ layer 4604a and the second SiO₂ layer 4604b adjoin to form an SiO₂ layer 4604, such that the InP waveguide 432 is encapsulated by the SiO₂ layer 4604 from the bottom and side of the InP waveguide 432.

In some embodiments, a top surface of the second SiO₂ layer 4604b is flush with a top surface of the p-InP layer 4325.

In some embodiments, before the second SiO₂ layer is formed, the p-InP layer 4325 is further etched such that the size of the top of the p-InP layer 4325 is greater than the size of the bottom of the p-InP layer 4325. For example, inclined surfaces are respectively formed on both sides of the p-InP layer 4325.

S700: form a radio frequency pad, a direct current bias pad, a radio frequency traveling waveguide, and an electrode on a top of the second SiO₂ layer; where the radio frequency pad is disposed at a side of one end of the InP waveguide, the radio frequency traveling waveguide is disposed at a side of a top edge of the InP waveguide, and one end of the radio frequency traveling waveguide is electrically connected to the radio frequency pad; the direct current bias pad is located at a side of the other end of the InP waveguide, and the direct current bias pad is electrically connected to the InP waveguide; the coupling electrode is located above the InP waveguide; and the coupling electrode is electrically connected to the radio frequency traveling waveguide.

The radio frequency pad 440, the direct current bias pad 461, the radio frequency traveling waveguide 450, and the coupling electrode 433 on the top of the second SiO₂ layer 4604 are formed by electroplating, where the coupling electrode 433 is located above the p-InP layer 4325, and the radio frequency traveling waveguide 450 is located at a side above the p-InP layer 4325.

In some embodiments, a first resistor 464, a second resistor 465, a capacitor 466, and a terminal pad 463 are further formed on the top of the second SiO₂ layer 4604. The first resistor 464, the second resistor 465, the capacitor 466, and the terminal pad 463 can be formed by electroplating.

A specific form of the hybrid InP/Si optical chip fabricated by the fabrication method for a hybrid InP/Si optical chip provided in the embodiments of the present disclosure can refer to a structure of the hybrid InP/Si optical chip provided in the above embodiments of the present disclosure.

The above descriptions are merely specific embodiments of the present disclosure, but the scope of protection of the present disclosure is not limited thereto. Any of those skilled in the art can think of changes or substitutions within the technical scope of the present disclosure, and these changes or substitutions shall all be included within the scope of protection of the present disclosure. Therefore, the scope of protection of the present disclosure shall be subject to the scope of protection of the claims.

What is claimed is:

1. An optical module, comprising:
a circuit board; and
a hybrid InP/Si optical chip, electrically connected to the circuit board, and configured to modulate and generate an optical signal,
wherein the hybrid InP/Si optical chip comprises:
an Si platform, integrated with a silicon photonic circuit, wherein an InP region is formed inside the Si platform, the InP region is absent from a pad, a radio frequency pad and a direct current bias pad are disposed on a top of the Si platform, the radio frequency pad is located on one side of the InP region, and the direct current bias pad is located on the other side of the InP region;
an InP phase modulator, located within the InP region, wherein the InP phase modulator comprises an InP waveguide and a coupling electrode, the coupling electrode is disposed above the InP waveguide, and the InP waveguide is electrically connected to the direct current bias pad; and
a radio frequency traveling waveguide, one end of the radio frequency traveling waveguide being connected to the radio frequency pad, and the other end of the radio frequency traveling waveguide extending over the InP waveguide and further extending to the other side of the InP region, wherein the radio frequency traveling waveguide is electrically connected to the coupling electrode;
the radio frequency pad comprises a first radio frequency pad and a second radio frequency pad, the radio frequency traveling waveguide comprises a first radio frequency electrode and a second radio frequency electrode, one end of the first radio frequency electrode is connected to the first radio frequency pad, and one end of the second radio frequency electrode is connected to the second radio frequency pad;
the first radio frequency electrode spans the InP region along one side of a top of the InP waveguide, and the second radio frequency electrode spans the InP region along the other side of a top of the InP waveguide;
the first radio frequency electrode extends from one side outside the InP region to the other side outside the InP region, and the second radio frequency electrode extends from the side outside the InP region to the other side outside the InP region; and
the Si platform includes a substrate layer, a BOX layer is disposed above the substrate layer, an Si waveguide layer and an SiO₂ layer are disposed above the BOX layer, the Si waveguide layer is encapsulated by the SiO₂ layer, the Si waveguide layer includes a strip-shaped Si waveguide, and a top of the SiO₂ layer supports the first radio frequency electrode and the second radio frequency electrode.

2. The optical module according to claim 1, wherein a middle portion of the first radio frequency electrode is located above one side edge of the InP waveguide, a middle portion of the second radio frequency electrode is located above the other side edge of the InP waveguide, and the first radio frequency electrode and the second radio frequency electrode are respectively connected to the corresponding coupling electrodes on the top of the InP waveguide.

3. The optical module according to claim 2, wherein the first radio frequency electrode comprises a first connecting section, a parallel section, and a second connecting section, and the parallel section is located above the side edge of the InP waveguide; one end of the first connecting section is connected to the first radio frequency pad, the other end of the first connecting section is connected to one end of the parallel section, the other end of the parallel section is connected to one end of the second connecting section, and the other end of the second connecting section is located outside the InP region; and the first connecting section is configured as a transitional connection from the first radio frequency pad to the parallel section, and the second connecting section is configured as a transitional connection from the parallel section to a tail end of the first radio frequency electrode.

4. The optical module according to claim 3, wherein the first connecting section comprises a first connection region, a first transition region, a second connection region and a second transition region;
one end of the first connection region is connected to the first radio frequency pad, the other end of the first connection region is connected to one end of the first transition region, the other end of the first transition region is connected to one end of the second connection region, the other end of the second connection region is connected to one end of the second transition region, and the other end of the second transition region is connected to one end of the parallel section; and
the first connection region is located outside the InP region, the end of the first transition region is located outside the InP region and the other end of the first transition region is located inside the InP region, and the second connection region and the second transition region are located outside the InP region; and a width of the end of the first transition region is greater than a width of the other end of the first transition region, and a width of one end of the second transition region is greater than a width of the other end of the second transition region.

5. The optical module according to claim 3, wherein the second connecting section comprises a third transition region, a third connection region, and a fourth transition region;
one end of the third transition region is connected to the other end of the parallel section, the other end of the third transition region is connected to one end of the third connection region, the other end of the third connection region is connected to one end of the fourth transition region, and the other end of the fourth transition region is connected to the tail end of the first radio frequency electrode; and
the third transition region and the third connection region are located within the InP region, one end of the fourth transition region is located within the InP region and the other end of the fourth transition region is located outside the InP region; and a width of the end of the third transition region is smaller than a width of the other end of the third transition region, and a width of the end of the fourth transition region is less than a width of the other end of the fourth transition region.

6. The optical module according to claim 1, wherein the coupling electrodes are provided in pairs, each pair of coupling electrodes is located between the first radio frequency electrode and the second radio frequency electrode, each pair of coupling electrodes comprises a first electrode and a second electrode, the first electrode and the second electrode are located above the InP waveguide, tops of the first electrode and the second electrode are disposed opposite to each other with a gap between the first electrode and the second electrode, a bottom of the first electrode is electrically connected to the first radio frequency electrode, and a bottom of the second electrode is electrically connected to the second radio frequency electrode.

7. The optical module according to claim 6, wherein the first electrode and the second electrode are both "T"-shaped electrodes.

8. The optical module according to claim 1, wherein the InP waveguide comprises an n-InP layer, the n-InP layer comprises a first n-InP protrusion and a second n-InP protrusion, and a gap is formed between the first n-InP protrusion and the second n-InP protrusion; and
tops of the first n-InP protrusion and the second n-InP protrusion are sequentially provided with a first i-InP layer, a quantum well layer, a second i-InP layer, and a p-InP layer, respectively; the coupling electrode comprises a first electrode and a second electrode; the first electrode is disposed on the p-InP layer above the first n-InP protrusion, and the second electrode is disposed on the p-InP layer above the second n-InP protrusion.

9. The optical module according to claim 8, wherein an SiO₂ material is filled in gaps among the first i-InP layer, the quantum well layer, the second i-InP layer, and the p-InP layer, such that the InP waveguide is encapsulated by an SiO₂ layer.

10. The optical module according to claim 1, wherein the hybrid InP/Si optical chip further comprises a first resistor, a second resistor, a capacitor, and a terminal pad that are all disposed outside the InP region; and
one end of the first resistor is electrically connected to the other end of the first radio frequency electrode, and the other end of the first resistor is electrically connected to the terminal pad; one end of the second resistor is electrically connected to the second radio frequency electrode, and the other end of the second resistor is electrically connected to the terminal pad; and one end of the capacitor is connected between the other end of the first resistor and the other end of the second resistor, and the other end of the capacitor is grounded.

11. The optical module according to claim 1, wherein a Si waveguide is provided in the Si platform, and the Si waveguide comprises an optical input Si waveguide and an optical output Si waveguide;
one end of the optical input Si waveguide is located outside the InP region and extends below the InP waveguide, and the other end of the optical input Si waveguide is located below one end of the InP waveguide, such that the optical input Si waveguide couples unmodulated light into the InP waveguide; and
one end of the optical output Si waveguide is located below the other end of the InP waveguide and extends in a direction away from the InP waveguide, such that light modulated by the InP waveguide is coupled into the optical output Si waveguide and output through the optical output Si waveguide.

12. The optical module according to claim 11, wherein a size of the top of the optical input Si waveguide is smaller than a size of a bottom of the optical input Si waveguide.

13. The optical module according to claim 1, wherein the optical module further comprises a hybrid InP/Si optical chip assembly, and the hybrid InP/Si optical chip assembly comprises:
a substrate, provided with a high-frequency transmission line;
a driver, disposed on the substrate and connected to one end of the high-frequency transmission line; and
the hybrid InP/Si optical chip, disposed on the substrate and connected to the other end of the high-frequency transmission line.

14. A fabrication method for a hybrid InP/Si optical chip, wherein the hybrid InP/Si optical chip is configured to modulate and generate an optical signal, and the fabrication method comprises:
forming a first substrate, wherein the first substrate comprises a substrate layer and a BOX layer, and the BOX layer is located above the substrate layer;
forming an Si waveguide layer above the BOX layer, and etching the Si waveguide layer to form an input Si waveguide and an output Si waveguide, wherein a gap is formed between the input Si waveguide and the output Si waveguide;
forming a first SiO₂ layer around the etched Si waveguide layer, wherein the first SiO₂ layer fills a region that is of the Si waveguide layer and etched away;
disposing an InP bare die above the first SiO₂ layer;
etching the InP bare die to form an InP waveguide;
forming a second SiO₂ layer on a side of the InP waveguide, wherein the first SiO₂ layer and the second SiO₂ layer together form an SiO₂ layer, and the Si waveguide layer is encapsulated by the SiO₂ layer; and
forming a radio frequency pad, a direct current bias pad, a radio frequency traveling waveguide, and a coupling electrode on a top of the second SiO₂ layer; wherein the radio frequency pad is disposed at a side of one end of the InP waveguide, the radio frequency traveling waveguide is disposed at a side of a top edge of the InP waveguide, and one end of the radio frequency traveling waveguide is electrically connected to the radio frequency pad; the direct current bias pad is located at a side of the other end of the InP waveguide, and the direct current bias pad is electrically connected to the InP waveguide; the coupling electrode is located above the InP waveguide; and the coupling electrode is electrically connected to the radio frequency traveling waveguide.

15. The fabrication method according to claim 14, wherein the InP bare die comprises, from bottom to top, an n-InP layer, a first i-InP layer, a quantum well layer, a second i-InP layer, a p-InP layer, and a second substrate; a bottom of the InP waveguide forms a first n-InP protrusion and a second n-InP protrusion on a top of the n-InP layer, a gap is formed between the first n-InP protrusion and the second n-InP protrusion, and a top of the first n-InP protrusion and a top of the second n-InP protrusion respectively support the first i-InP layer, the quantum well layer, the second i-InP layer, and the p-InP layer; the coupling electrode comprises a first electrode and a second electrode; and the first electrode is disposed on the p-InP layer above the first n-InP protrusion, and the second electrode is disposed on the p-InP layer above the second n-InP protrusion.

16. The fabrication method according to claim 15, wherein an SiO₂ material is filled in gaps among the first i-InP layer, the quantum well layer, the second i-InP layer and the p-InP layer, such that the InP waveguide is encapsulated by the SiO₂ layer.

17. The fabrication method according to claim 14, wherein the fabrication method further comprises:
sequentially growing a p-InP layer, a second i-InP layer, a quantum well layer, a first i-InP layer, and an n-InP layer on a second substrate to form the InP bare die.

18. The fabrication method according to claim 14, wherein the radio frequency pad comprises a first radio frequency pad and a second radio frequency pad, the radio frequency traveling waveguide comprises a first radio frequency electrode and a second radio frequency electrode, one end of the first radio frequency electrode is connected to the first radio frequency pad, and one end of the second radio frequency electrode is connected to the second radio frequency pad; and
a middle portion of the first radio frequency electrode is located above one side edge of the InP waveguide, a middle portion of the second radio frequency electrode is located above the other side edge of the InP waveguide, and the first radio frequency electrode and the second radio frequency electrode are respectively connected to the corresponding coupling electrodes on the top of the InP waveguide.

19. The fabrication method according to claim 18, further comprising:
forming a first resistor, a second resistor, a capacitor, and a terminal pad on the top of the second SiO₂ layer, wherein the first resistor, the second resistor, the capacitor, and the terminal pad are located at a side of the top of the InP waveguide; and
one end of the first resistor is electrically connected to the other end of the first radio frequency electrode, and the other end of the first resistor is electrically connected to the terminal pad; one end of the second resistor is electrically connected to the second radio frequency electrode, and the other end of the second resistor is electrically connected to the terminal pad; and one end of the capacitor is connected between the other end of the first resistor and the other end of the second resistor, and the other end of the capacitor is grounded.

20. The fabrication method according to claim 14, wherein the input Si waveguide extends from an edge of one end of the BOX layer to an edge of one end of a bottom of the n-InP layer;
the output Si waveguide extends from an edge of the other end of a bottom of the n-InP layer to an edge of the other end of the BOX layer; and
the coupling electrode is a "T"-shaped electrode, and a bottom of the coupling electrode is connected to the radio frequency traveling waveguide.
